(19) United States
(12) Patent Application Publication
(10) Pub. No.: US 2019/0388837 A1
(43) Pub. Date: Dec. 26, 2019

(54) Waste Gas Processing Device, Vacuum Coating System, and Operation Method of Waste Gas processing Device

(71) Applicant: Dongtai Hi-Tech Equipment Technology Co., Ltd, Beijing (CN)

(72) Inventors: Ji NING, Beijing (CN); Xinyun ZHANG, Beijing (CN); Changle GUAN, Beijing (CN); Jianhui Nan, Beijing (CN)

(21) Appl. No.: 16/171,380

(22) Filed: Oct. 26, 2018

(30) Foreign Application Priority Data
Jun. 21, 2018 (CN) 201810644930.9

(51) Int. Cl. B01D 53/75; B01D 53/48; B01D 53/86; B01J 37/02; B01D 53/78

(52) U.S. Cl. CPC B01D 53/75; B01D 53/48; C23C 14/56; B01J 37/0215; B01D 53/78; B01D 53/8603

(57) ABSTRACT

Provided are a waste gas processing device, a vacuum coating system, and an operation method of a waste gas processing device. The waste gas processing device is configured to remove and recover arsenic in waste gas, and includes a condensation portion and a scraping portion. The condensation portion is provided with a condensation cavity, and an air inlet, an air outlet and a discharge port communicated with the condensation cavity. The condensation portion is configured to cool waste gas charged into the condensation cavity from the air inlet, so that gaseous arsenic in the waste gas is condensed on an inner wall surface of the condensation cavity by cooling to form solid arsenic. The scraping portion is rotatably provided in the condensation cavity, and a partial surface of the scraping portion abuts against the inner wall surface of the condensation cavity.

The present application claims the benefit of priority to China Patent Application No. 201810644930.9, filed on Jun. 21, 2018 and entitled “Waste Gas Processing Device, Vacuum Coating System, and Operation Method of Waste Gas Processing Device”, the contents of which are hereby incorporated by reference in its entirety.

### TECHNICAL FIELD

The present disclosure relates to a technical field of waste gas processing, and in particular to a waste gas processing device, a vacuum coating system, and an operation method of a waste gas processing device.

### BACKGROUND

A waste gas generated by a vacuum coating, machine contains arsenic particles. If arsenic in the waste gas is directly discharged into an external environment, the environment will be polluted, and a physical health of people will be harmed.

In the related art, in order to solve the technical problem, waste gas is usually sprayed, by a strong oxidant water solution, and arsenic in the waste gas is separated and collected in a manner of adding a high speed centrifugation device. This solution needs to consume a chemical reagent so as to cause a higher economic cost for waste gas processing. In addition, this solution may also generate waste water and water-containing waste gas, so as to increase subsequent waste gas processing steps, thereby increasing an economic cost for waste gas processing.

### SUMMARY

Some embodiments of the present disclosure provide a waste gas processing device, a vacuum coating system, and an operation method of a waste gas processing device, intended to solve the problem in the related art that the economic cost of a waste gas processing device is too high during the removal and recovery of arsenic in waste gas.

According to some embodiments of the present disclosure, a waste gas processing device is provided for removing and recovering arsenic in waste gas. In an exemplary embodiment, the waste gas processing device includes: a condensation portion, and the condensation portion is provided with a condensation cavity, and an air inlet, an air outlet and a discharge port communicated with the condensation cavity, the condensation portion being configured to cool waste gas charged into the condensation cavity from the air inlet, so that gaseous arsenic in the waste gas is condensed on an inner wall surface of the condensation cavity by cooling to form solid arsenic; and a scraping portion, the scraping portion being rotatably provided in the condensation cavity, a partial surface of the scraping portion abutting against the inner wall surface of the condensation cavity, the scraping portion rotating to scrape the solid arsenic off, and scraped-off solid arsenic continuously moving toward the discharge port under a rotary pushing action of the scraping portion.

In an exemplary embodiment, the scraping portion includes a plurality of scraping screw rods, each scraping screw rod is provided along a length direction of the condensation cavity, every two adjacent scraping screw rods are provided in contact with each other, and screw blades of every two adjacent scraping screw rods are staggered.

In an exemplary embodiment, there are two scraping screw rods, the condensation cavity includes two sub-installation cavities communicated with each other, a communicated opening of the two sub-installation cavities is a strip-shaped opening continuously extending along the length direction of the condensation cavity, a cross section of each sub-installation cavity is round, and the two scraping screw rods are provided in the two sub-installation cavities in a one-to-one correspondence manner.

In an exemplary embodiment, the scraping portion further includes a bearing, two ends of each scraping screw rod are connected with the condensation portion through one bearing respectively, and the bearing is embedded into the condensation portion.

In an exemplary embodiment, the condensation portion also is provided with an overflow cavity, a liquid inlet and a liquid outlet, wherein the overflow cavity and the condensation cavity are provided at an interval, both the liquid inlet and the liquid outlet are communicated with the overflow cavity, and a coolant flows through the liquid inlet, the overflow cavity and the liquid outlet in sequence to control an internal temperature of the condensation cavity.

In an exemplary embodiment, the condensation portion includes: a condensation portion body, the overflow cavity being provided inside the condensation portion body; and two end covers, the two end covers detachably covering two ends of the condensation portion body, and the condensation cavity is surrounded by the two end covers and the condensation portion body together.

In an exemplary embodiment, the waste gas processing device further includes a driving portion, the driving portion including: an installation plate, the installation plate being connected with the condensation portion; and a driving member, the driving member being provided on the installation plate, the driving member driving a driving gear to rotate, and an end, close to the driving member, of each scraping screw rod being provided with a driven gear meshed with the driving gear.

In an exemplary embodiment, the discharge port is provided on the condensation portion body, the discharge port is provided at a bottom of the condensation portion body in a vertical direction, and the discharge port is located at an end, away from the driving portion, of the condensation portion body.

In an exemplary embodiment, each scraping screw rod is supported between the two end covers, and the each scraping screw rod is sealingly connected with the end covers.

According to some embodiments of the present disclosure, a vacuum coating system is provided. The vacuum coating system includes: a vacuum coating machine, the vacuum coating machine having a waste gas discharge outlet; and a waste gas processing device, an air inlet of the waste gas processing device being communicated with an air outlet, the waste gas processing device being the foregoing waste gas processing device.

According to some embodiments of the present disclosure, an operation method of a waste gas processing device is provided for operating the foregoing waste gas processing device. The method includes the following steps. In step Si , a temperature of a condensation cavity of a condensation portion is controlled to be lower than a freezing point of arsenic. In step S2, a waste gas is charged into the condensation cavity from an air inlet of the condensation portion, wherein gaseous arsenic in the waste gas comes into contact with an inner wall surface of the condensation cavity and is condensed on the inner wall surface of the condensation cavity by cooling to form solid arsenic, and a treated waste gas is discharged out of the condensation cavity from an air outlet of the condensation portion. In step S3, a driving portion of the waste gas processing device is controlled to be started, wherein the driving portion drives a scraping portion to rotate, the scraping portion rotates to scrape the solid arsenic off, and the scraped-off solid arsenic continuously moves toward a discharge port under a rotary pushing action of the scraping portion and is discharged from the discharge port.

By applying the technical solution of the present disclosure, a condensation portion and a scraping portion are provided. The condensation portion is configured to cool waste gas charged into a condensation cavity from an air inlet to make gaseous arsenic in the waste gas condensed on an inner wall surface of the condensation cavity to form solid arsenic. The scraping portion rotates to scrape the solid arsenic off, the scraped-off solid arsenic continuously moves toward a discharge port under the rotary pushing action of the scraping portion, and the solid arsenic is then discharged out of the condensation cavity from the discharge port, so that arsenic in the waste gas can be removed and recovered. The waste gas processing device provided in some embodiments of the present application is simple in structure and low in economic cost, and can effectively remove and recover arsenic in waste gas.

In an exemplary embodiment, when the scraping portion includes a plurality of scraping screw rods, two adjacent scraping screw rods are provided in contact with each other, and screw blades of the two adjacent scraping screw rods are staggered. The scraping screw rod rotates to scrape off solid arsenic condensed on the inner wall surface of the condensation cavity. Furthermore, solid arsenic condensed on the adjacent scraping screw rod is also scraped off, and the scraped-off solid arsenic moves to the discharge port under a forced conveying action of the scraping screw rod, so as to avoid from reducing the quantity of recovered solid arsenic caused by excessive solid arsenic condensed on the scraping portion or affecting the scraping effect of the scraping portion.

### BRIEF DESCRIPTION OF THE DRAWINGS

The accompanying drawings, which constitute a part of this application, are used to provide a further understanding of the present disclosure, and the exemplary embodiments of the present disclosure and the description thereof are used to explain the present disclosure, but do not constitute improper limitations to the present disclosure. In the drawings:

FIG. 1 illustrates a structural schematic diagram of a waste gas processing device according to an alternative embodiment of the present disclosure;

FIG. 2 illustrates a front section view of the waste gas processing device in FIG. 1;

FIG. 3 illustrates a left section view of the waste gas processing device in FIG. 2;

FIG. 4 illustrates a top section view of the waste gas processing device in FIG. 1; and

FIG. 5 illustrates a left view of a partial structure of the waste gas processing device in FIG. 4.

The drawings include the following reference signs:
10: condensation portion;
11: condensation cavity;
12: air inlet;
13: air outlet;
14: discharge port;
20: scraping portion;
21: scraping screw rod;
111: sub-installation cavity;
22: bearing;
15: overflow cavity;
16: liquid inlet;
17: liquid outlet;
18: condensation portion body;
19: end cover;
30: driving portion;
31: installation plate;
32: driving member;
33: driving gear;
34: driven gear;
40: magnetic fluid.

### DETAILED DESCRIPTION OF THE EMBODIMENTS

The technical solutions in the embodiments of the present disclosure will be clearly and completely described herein below with the drawings in the embodiments of the present disclosure. It is apparent that the described embodiments are only part of the embodiments of the present disclosure, not all of the embodiments. The following description of at least one exemplary embodiment is only illustrative actually, and is not used as any limitation for the present disclosure and the application or use thereof. On the basis of the embodiments of the present disclosure, all other embodiments obtained on the premise of no creative work of those of ordinary skill in the art fall within the scope of protection of the present disclosure.

In order to solve the problem in the related art that the economic cost of a waste gas processing device is too high during the removal and recovery of arsenic in waste gas, some embodiments of the present disclosure provides a waste gas processing device, a vacuum coating system, and an operation method of a waste gas processing device. The vacuum coating system includes the foregoing and following waste gas processing device, and the operation method of a waste gas processing device is used for operating the foregoing and following waste gas processing device.

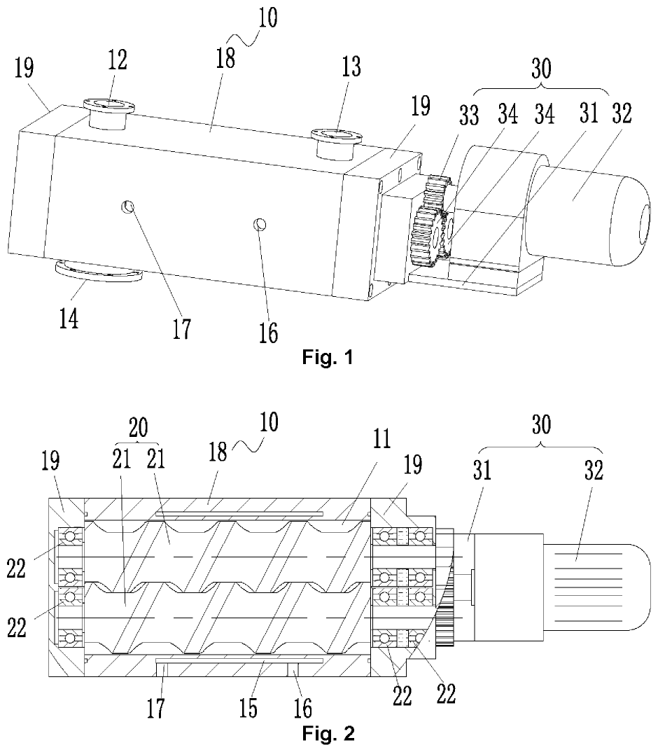

As shown in FIG. 1 to FIG. 5, a waste gas processing device for removing and recovering arsenic in waste gas includes a condensation portion 10 and a scraping portion 20. The condensation portion 10 is provided with a condensation cavity 11, and an air inlet 12, an air outlet 13 and a discharge port 14 communicated with the condensation cavity 11. The condensation portion 10 is configured to cool the waste gas charged into the condensation cavity 11 from the air inlet 12, so that gaseous arsenic in the waste gas is condensed on an inner wall surface of the condensation cavity 11 by cooling to form solid arsenic. The scraping portion 20 is rotatably provided in the condensation cavity 11, and a partial surface of the scraping portion 20 is configured to abut against the inner wall surface of the condensation cavity 11. The scraping portion 20 rotates to scrape the solid arsenic off, and a scraped-off solid arsenic continuously moves toward the discharge port 14 under a rotary pushing action of the scraping portion 20.

In some embodiments of the present disclosure, the condensation portion 10 and the scraping portion 20 are provided. The condensation portion 10 is configured to cool waste gas charged into the condensation cavity 11 from the air inlet 12 to make gaseous arsenic in the waste gas condensed on an inner wall surface of the condensation cavity 11 to form solid arsenic. The scraping portion 20 rotates to scrape the solid arsenic off, the scraped-off solid arsenic continuously moves toward the discharge port 14 under the rotary pushing action of the scraping portion 20, and the solid arsenic is then discharged out of the condensation cavity 11 from the discharge port 14, so that the arsenic in the waste gas can be removed and recovered. The waste gas processing device provided in an embodiment is simple in structure and low in economic cost, and can effectively remove and recover arsenic in waste gas.

In some embodiments of the present disclosure, an internal temperature of the condensation cavity 11 is controlled to be lower than a freezing point of arsenic, so that the gaseous arsenic in the waste gas is condensed into sheet-like solid arsenic and attached to the inner wall of the condensation cavity 11.

As shown in FIG. 1, in some embodiments of the present disclosure, the scraping portion 20 includes a plurality of scraping screw rods 21, each scraping screw rod 21 is provided along a length direction of the condensation cavity, every two adjacent scraping screw rods 21 are provided in contact with each other, and screw blades of every two adjacent scraping screw rods 21 are staggered. Thus, the scraping screw rod 21 rotates to scrape off solid arsenic condensed on the inner wall surface of the condensation cavity 11. Solid arsenic condensed on the adjacent scraping screw rod 21 is also scraped off, so as to avoid from reducing the quantity of recovered solid arsenic caused by excessive solid arsenic condensed on the scraping portion 20 or affecting the scraping effect of the scraping portion 20.

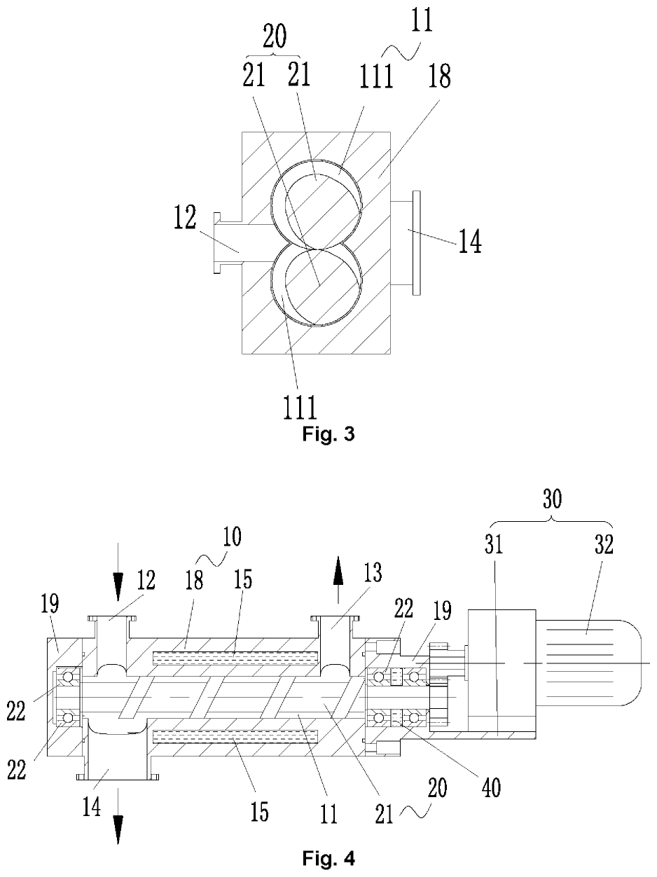

In an exemplary embodiment, as shown in FIG. 3, there are two scraping screw rods 21, the condensation cavity 11 includes two sub-installation cavities 111 communicated with each other, a communicated opening of the two sub-installation cavities 111 is a strip-shaped opening continuously extending along the length direction of the condensation cavity 11, a cross section of each sub-installation cavity 111 is round, and the two scraping screw rods 21 are provided in the two sub-installation cavities 111 in a one-to-one correspondence manner. Thus, the two scraping screw rods 21 rotate in a same direction, and solid arsenic condensed on the inner walls of the two sub-installation cavities 111 is scraped off respectively, moves toward the discharge port 14 under the rotary pushing action of the scraping screw rods 21, and is discharged out of the condensation cavity 11 from the discharge port 14, so that arsenic in the waste gas can be removed and recovered.

In an exemplary embodiment, as shown in FIG. 2 and FIG. 4, the scraping portion 20 also includes a plurality of bearings 22, two ends of each scraping screw rod 21 are connected with the condensation portion 10 through one bearing 22 respectively, and the bearing 22 is embedded into the condensation portion 10. Thus, the scraping screw rod 21 is provided in the condensation portion 10 through the bearing 22 in a pivoted manner.

In an exemplary embodiment, as shown in FIG. 1, FIG. 2 and FIG. 4, the condensation portion 10 also has an overflow cavity 15, a liquid inlet 16 and a liquid outlet 17, wherein the overflow cavity 15 and the condensation cavity 11 are provided at an interval, both the liquid inlet and the liquid outlet are communicated with the overflow cavity 15, and a coolant flows through the liquid inlet 16, the overflow cavity 15 and the liquid outlet 17 in sequence to control the internal temperature of the condensation cavity 11. Thus, the coolant is circularly charged into the overflow cavity 15 so as to control the internal temperature of the condensation cavity 11, thereby cooling the waste gas in the condensation cavity 11.

As shown in FIG. 1, FIG. 2 and FIG. 4, in an exemplary embodiment, the condensation portion 10 includes a condensation portion body 18 and two end covers 19. The overflow cavity 15 is provided inside the condensation portion body 18. The liquid inlet 16 and the liquid outlet 17 are provided on the condensation portion body 18. The two end covers 19 detachably cover two ends of the condensation portion body 18. The condensation cavity 11 is surrounded by the two end covers 19 and the condensation portion body 18 together. Thus, the condensation portion body 18 and the two end covers 19 are provided detachably, thereby it is convenient for producing the condensation portion 10 and also convenient for replacing the scraping portion 20.

In an exemplary embodiment, as shown in FIG. 1, the condensation portion body 18 is a cuboid, which can increase the placement stability of the waste gas processing device. In an exemplary embodiment, as shown in FIG. 3, the cross section area of the condensation cavity 11 is of 8-shaped, which makes the scraping portion 20 come into contact with the entire inner wall surface of the condensation cavity 11 during rotation, thereby avoiding existing a scraping dead corner of the scraping portion 20.

A clearance is provided between the scraping screw rod 21 and the inner wall of the condensation cavity 11 and may be taken as a waste gas flowing passage. In addition, a continuous small oval chamber is formed between two scraping screw rods 21 rotating in the same direction in parallel, and may also be taken as a waste gas flowing passage.

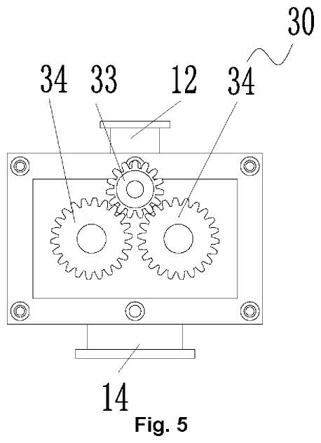

In an exemplary embodiment, as shown in FIG. 1, FIG. 2, FIG. 4, and FIG. 5, the waste gas processing device includes a driving portion 30, wherein the driving portion 30 includes an installation plate 31, a driving member 32, a driving gear 33, and a driven gear 34. The installation plate 31 is connected with the condensation portion 10. The driving member 32 is provided on the installation plate 31, the driving member 32 drives the driving gear 33 to rotate, and an end, close to the driving member 32, of each scraping screw rod 21 is provided with the driven gear 34 meshed with the driving gear 33.

Alternatively, the driving member 32 is a motor, a hydraulic motor or a rotary cylinder, and the motor, the hydraulic motor or the rotary cylinder is controlled to be started to drive the scraping portion 20 to rotate. In an alternative embodiment shown in FIG. 1 and FIG. 2, the driving member 32 is a motor.

In a non-illustrated embodiment of the present application, the driving member 32 drives a driving chain wheel to rotate, an end, close to the driving member 32, of each scraping screw rod 21 is provided with a driven chain wheel matched with the driving chain wheel, a transmission chain sleeves the driving chain wheel and the driven chain wheel, and the driving chain wheel drives the driven chain wheel through the transmission chain.

In another non-illustrated embodiment of the present application, the driving member 32 drives a driving belt wheel to rotate, and an end, close to the driving member 32, of each scraping screw rod 21 is provided with a driven belt wheel matched with the driving belt wheel, a transmission belt is provided on the driving belt wheel and the driven belt wheel in a sleeve manner, and the driving belt wheel drives the driven belt wheel through the transmission belt.

In another non-illustrated embodiment of the present application, there is a plurality of driving members 32, each driving member 32 is in driving connection with each scraping screw rod 21, and the various driving members 32 are controlled to be simultaneously started to drive the various scraping screw rods 21 to rotate in the same direction.

As shown in FIG. 1 and FIG. 4, the discharge port 14 is provided on the condensation portion body 18, the discharge port 14 is located at a bottom of the condensation portion body 18 in a vertical direction, and the discharge port 14 is located at an end, away from the driving portion 30, of the condensation portion body 18. Thus, the scraped-off solid arsenic moves away from the driving portion 30 along with the rotary pushing of the scraping screw rod 21, and then is discharged out of the condensation cavity 11 under an action of gravity.

In an alternative embodiment shown in FIG. 1 and FIG. 4, the air inlet 12, the air outlet 13 and the discharge port 14 are all provided on the condensation portion body 18. The air outlet 13 is located at a top of the condensation portion body 18 in the vertical direction, the air outlet 13 is located at an end, close to the driving portion 30, of the condensation portion body 18, and the air inlet 12 and the air outlet 13 are provided oppositely or the air inlet 12 and the discharge port 14 are provided oppositely. In an exemplary embodiment, there is a plurality of air inlets 12, air outlets 13 and discharge ports 14.

As shown in FIG. 2 and FIG. 4, the scraping screw rod 21 is supported between the two end covers 19, and the scraping screw rod 21 is sealingly connected with the end covers 19. By the sealed connection of the scraping screw rod 21 and the end cover 19, the waste gas in the condensation cavity 11 is prevented from leaking into an external environment, thereby improving the use safety of the waste gas processing device.

In an exemplary embodiment, a sealing ring is provided between the scraping screw rod 21 and the end cover 19, so that the scraping screw rod 21 and the end cover 19 are sealingly connected.

In some other embodiments, a magnetic fluid 40 is provided between the scraping screw rod 21 and the end cover 19, so that the scraping screw rod 21 and the end cover 19 are sealingly connected.

The present application also provides a vacuum coating system. In some embodiments of the present disclosure, the vacuum coating system includes a vacuum coating machine and a waste gas processing device. The vacuum coating machine has a waste gas discharge outlet, and an air inlet 12 of the waste gas processing device is communicated with an air outlet 13. The waste gas processing device is the foregoing waste gas processing device. Thus, the vacuum coating system provided in the present application generates, during the production process of coating a substrate with gallium arsenide, waste gas containing gaseous arsenic, and the air inlet 12 of the waste gas processing device is communicated with the waste gas discharge outlet, so that the waste gas generated by the vacuum coating system is charged into the waste gas processing device, and arsenic is removed and recovered.

In an exemplary embodiment, the vacuum coating system includes a filter for removing arsenic, the waste gas treated by the waste gas processing device is charged into the filter, and residual arsenic in the waste gas is further treated, thereby improving the environmental protection performance of the vacuum coating system. In addition, since there is little arsenic treated by the filter, it is unnecessary to frequently replace a filter element, so as to reduce the economic cost of the vacuum coating system for waste gas processing.

The vacuum coating machine is controlled to stop working for manual replacement of the filter element, so that the labor intensity of a worker is improved, the physical health of the worker is harmed, and the production efficiency of the vacuum coating machine is affected. The vacuum coating system provided in the present application does not need to frequently replace the filter element, thereby improves the production efficiency of the vacuum coating machine, and reduces the economic cost of the vacuum coating system.

Some embodiments of the present disclosure also provide an operation method of a waste gas processing device, for operating the foregoing waste gas processing device. The method includes the following steps. In step S1, the temperature of a condensation cavity 11 of a condensation portion 10 is controlled to be lower than a freezing point of arsenic. In step S2, waste gas is charged into the condensation cavity 11 from an air inlet 12 of the condensation portion 10, wherein gaseous arsenic in the waste gas comes into contact with an inner wall surface of the condensation cavity 11 and is condensed on the inner wall surface of the condensation cavity 11 by cooling to form solid arsenic, and the treated waste gas is discharged out of the condensation cavity 11 from an air outlet 13 of the condensation portion 10. In step S3, a driving portion 30 is controlled to be started, wherein the driving portion 30 drives a scraping portion 20 to rotate, the scraping portion 20 rotates to scrape the solid arsenic off, and scraped-off solid arsenic continuously moves toward a discharge port 14 under a rotary pushing action of the scraping portion 20 and is discharged from the discharge port 14.

In a non-illustrated embodiment of the present disclosure, the scraping portion 20 includes three meshed scraping screw rods 21, the three scraping screw rods 21 are provided in a delta shape or provided adjacently in sequence.

The waste gas processing device provided in some embodiments of the present disclosure has the advantages as follows. A chemical method does not need to be adopted for removal, thereby saving a chemical reagent, and reducing the consumption of raw materials. It is unnecessary to dismount a condenser for manual removal, thereby reducing the labor intensity of a worker, and shortening the downtime maintenance time. The contact between the worker and arsenic is avoided, thereby improving the use safety of the waste gas processing device. When the waste gas processing device is used in cooperation with the filter, the life of a filter element may be greatly prolonged, thereby reducing the replacement frequency of the filter element of the filter. The sealing performance is good, and the leakage of the waste gas is avoided.

The above is only the exemplary embodiments of the present disclosure, not intended to limit the present disclosure. As will occur to those skilled in the art, the present disclosure is susceptible to various modifications and changes. Any modifications, equivalent replacements, improvements and the like made within the spirit and principle of the present disclosure shall fall within the scope of protection of the present disclosure.

What is claimed is:

1. A waste gas processing device, for removing and recovering arsenic in a waste gas, comprising:
a condensation portion, wherein the condensation portion is provided with a condensation cavity, and an air inlet, an air outlet and a discharge port communicated with the condensation cavity, the condensation portion being configured to cool the waste gas charged into the condensation cavity from the air inlet, so that gaseous arsenic in the waste gas is condensed on an inner wall surface of the condensation cavity by cooling to form solid arsenic; and
a scraping portion, the scraping portion being rotatably provided in the condensation cavity, a partial surface of the scraping portion abutting against the inner wall surface of the condensation cavity, the scraping portion rotating to scrape the solid arsenic off, and scraped-off solid arsenic continuously moving toward the discharge port under a rotary pushing action of the scraping portion.

2. The waste gas processing device as claimed in claim 1, wherein the scraping portion comprises a plurality of scraping screw rods, each scraping screw rod is provided along a length direction of the condensation cavity, every two adjacent scraping screw rods are provided in contact with each other, and screw blades of every two adjacent scraping screw rods are staggered.

3. The waste gas processing device as claimed in claim 2, wherein there are two scraping screw rods, the condensation cavity comprises two sub-installation cavities communicated with each other, a communicated opening of the two sub-installation cavities is a strip-shaped opening continuously extending along the length direction of the condensation cavity, a cross section of each sub-installation cavity is round, and the two scraping screw rods are provided in the two sub-installation cavities in a one-to-one correspondence manner.

4. The waste gas processing device as claimed in claim 2, wherein the scraping portion further comprises a bearing, two ends of each scraping screw rod are connected with the condensation portion through one bearing respectively, and the bearing is embedded into the condensation portion.

5. The waste gas processing device as claimed in claim 2, wherein the condensation portion also is provided with an overflow cavity, a liquid inlet and a liquid outlet, the overflow cavity and the condensation cavity are provided at an interval, both the liquid inlet and the liquid outlet are communicated with the overflow cavity, and a coolant flows through the liquid inlet, the overflow cavity and the liquid outlet in sequence to control an internal temperature of the condensation cavity.

6. The waste gas processing device as claimed in claim 5, wherein the condensation portion comprises:
a condensation portion body, the overflow cavity being provided inside the condensation portion body; and
two end covers, the two end covers detachably covering two ends of the condensation portion body, and the condensation cavity is surrounded by the two end covers and the condensation portion body.

7. The waste gas processing device as claimed in claim 6, further comprising a driving portion, the driving portion comprising:
an installation plate, the installation plate being connected with the condensation portion; and
a driving member, the driving member being provided on the installation plate, the driving member driving a driving gear to rotate, and an end, close to the driving member, of each scraping screw rod being provided with a driven gear meshed with the driving gear.

8. The waste gas processing device as claimed in claim 7, wherein the discharge port is provided on the condensation portion body, the discharge port is provided at a bottom of the condensation portion body in a vertical direction, and the discharge port is located at an end, away from the driving portion, of the condensation portion body.

9. The waste gas processing device as claimed in claim 6, wherein each scraping screw rod is supported between the two end covers, and the each scraping screw rod is sealingly connected with the end covers.

10. A vacuum coating system, comprising:
a vacuum coating machine, wherein the vacuum coating machine is provided with a waste gas discharge outlet; and
a waste gas processing device, the air inlet of the waste gas processing device being communicated with the air outlet, the waste gas processing device being the waste gas processing device as claimed in claim 1.

11. An operation method of a waste gas processing device, for operating the waste gas processing device as claimed in claim 1, comprising the following steps:
step S1: controlling a temperature of a condensation cavity of a condensation portion to be lower than a freezing point of arsenic;
step S2: charging a waste gas into the condensation cavity from an air inlet of the condensation portion, wherein gaseous arsenic in the waste gas comes into contact with an inner wall surface of the condensation cavity and is condensed on the inner wall surface of the condensation cavity by cooling to form solid arsenic, and a treated waste gas is discharged out of the condensation cavity from an air outlet of the condensation portion; and
step S3: controlling a driving portion of the waste gas processing device to be started, wherein the driving portion drives a scraping portion to rotate, the scraping portion rotates to scrape the solid arsenic off, and scraped-off solid arsenic continuously moves toward a discharge port under a rotary pushing action of the scraping portion and is discharged from the discharge port.

12. The waste gas processing device as claimed in claim 3, wherein the condensation portion also is provided with an overflow cavity, a liquid inlet and a liquid outlet, the overflow cavity and the condensation cavity are provided at an interval, both the liquid inlet and the liquid outlet are communicated with the overflow cavity, and a coolant flows through the liquid inlet, the overflow cavity and the liquid outlet in sequence to control an internal temperature of the condensation cavity.

13. A vacuum coating system, comprising:
a vacuum coating machine, wherein the vacuum coating machine is provided with a waste gas discharge outlet; and
a waste gas processing device, the air inlet of the waste gas processing device being communicated with the air outlet, the waste gas processing device being the waste gas processing device as claimed in claim 2.

14. A vacuum coating system, comprising:
a vacuum coating machine, wherein the vacuum coating machine is provided with a waste gas discharge outlet; and
a waste gas processing device, the air inlet of the waste gas processing device being communicated with the air outlet, the waste gas processing device being the waste gas processing device as claimed in claim 3.

15. A vacuum coating system, comprising:
a vacuum coating machine, wherein the vacuum coating machine is provided with a waste gas discharge outlet; and
a waste gas processing device, the air inlet of the waste gas processing device being communicated with the air outlet, the waste gas processing device being the waste gas processing device as claimed in claim 4.

16. A vacuum coating system, comprising:
a vacuum coating machine, wherein the vacuum coating machine is provided with a waste gas discharge outlet; and
a waste gas processing device, the air inlet of the waste gas processing device being communicated with the air outlet, the waste gas processing device being the waste gas processing device as claimed in claim 5.

17. A vacuum coating system, comprising:
a vacuum coating machine, wherein the vacuum coating machine is provided with a waste gas discharge outlet; and
a waste gas processing device, the air inlet of the waste gas processing device being communicated with the air outlet, the waste gas processing device being the waste gas processing device as claimed in claim 6.

18. A vacuum coating system, comprising:
a vacuum coating machine, wherein the vacuum coating machine is provided with a waste gas discharge outlet; and
a waste gas processing device, the air inlet of the waste gas processing device being communicated with the air outlet, the waste gas processing device being the waste gas processing device as claimed in claim 7.

19. A vacuum coating system, comprising:
a vacuum coating machine, wherein the vacuum coating machine is provided with a waste gas discharge outlet; and
a waste gas processing device, the air inlet of the waste gas processing device being communicated with the air outlet, the waste gas processing device being the waste gas processing device as claimed in claim 8.

20. A vacuum coating system, comprising:
a vacuum coating machine, wherein the vacuum coating machine is provided with a waste gas discharge outlet; and
a waste gas processing device, the air inlet of the waste gas processing device being communicated with the air outlet, the waste gas processing device being the waste gas processing device as claimed in claim 9.
